(19) United States
(12) Patent Application Publication
(10) Pub. No.: US 2005/0051908 A1
(43) Pub. Date: Mar. 10, 2005

(54) Diode exhibiting a high breakdown voltage

(76) Inventors: Masaki Ichinose, Nagano (JP); Akira Amano, Nagano (JP); Hideaki Ito, Nagano (JP); Hiroaki Furihata, Nagano (JP)

Correspondence Address: ROSSI & ASSOCIATES, P.O. BOX 826, ASHBURN, VA, 20146-0826, US

(21) Appl. No.: 10/898,887

(22) Filed: Jul. 26, 2004

(30) Foreign Application Priority Data
Jul. 25, 2003 (JP) JP 2003-201880

(51) Int. Cl. H01L 29/861; H01L 29/06; H01L 31/107

(52) U.S. Cl. 257/791; 257/788; 257/653; 257/603

(57) ABSTRACT

A diode exhibiting a high reverse breakdown voltage is manufactured by employing a flame-resisting epoxy resin, the extract of which when extracted under predetermined conditions exhibits electrical conductivity of 250 μS/cm or lower. According to the invention, sealant resins for high-voltage diodes with excellent moisture resistance are selected by employing the electrical resistance value found to be appropriate for a reference value not by assembling a high-voltage diode, but rather by conducting the predetermined humidity resistance test on the sealant resins. The sealant resin selection according to the invention facilitates reducing the resin costs, and, therefore, manufacturing high-voltage diodes exhibiting excellent humidity resistance with low manufacturing costs.

### CROSS REFERENCE TO RELATED APPLICATIONS

This application claims priority from application Serial No. JP 2003-201880, filed on Jul. 25, 2003, and the entire contents of this document are incorporated by reference in their entirety.

### BACKGROUND OF THE INVENTION

A. Field of the Invention

The present invention relates to a diode that exhibits a high reverse breakdown voltage (hereinafter referred to as a “high-voltage diode”) and that is sealed with a resin that exhibits excellent flame resistance, excellent moisture resistance, and excellent heat resistance. Specifically, the present invention relates to a high-voltage diode sealed with an epoxy resin that contains no halogen atoms.

B. Description of the Related Art

A high-voltage diode is a well-known example of a semiconductor device that exhibits a high breakdown voltage and is sealed with a flame resisting resin such as a flame-resisting epoxy resin. The high-voltage diode is a diode consisting of multiple diode chips such as silicon diode chips laminated so that the diode chip laminate exhibits a reverse breakdown voltage of from 5 kV to 50 kV. The high-voltage diode is used to rectify a high voltage AC waveform as high as several tens kV. Since the high-voltage diode is used in such a high voltage circuit, a flame resisting resin for sealing the diode chip laminate should be selected for safety under the conditions and in the environments where the high-voltage diode will be used. It is well known that the cresol-novolak epoxy resins are very suitable for sealing a high-voltage diode from the viewpoint of safety against hazards such as dielectric breakdown of the high-voltage diode. However, it has been discovered that the halogen-group-containing compounds and red phosphorus contained in or added to the resin to improve flame resistance are hazardous, since the halogen-group-containing compounds and the red phosphorus corrode the metal electrodes in the semiconductor device at high temperatures and yield intermetallic compounds which lower the bonding strength of the metal films, and cause parting and breaking of the metal films. Moreover, it is desirable for the sealant resin not to contain any halogen-group-containing compound or any red phosphorus so as not to cause environmental pollution when the semiconductor devices are discarded.

Japanese Unexamined Laid Open Patent Application 2003-133485 discloses epoxy resins to which any of the flame retardants described below is added. The flame retardants include metal oxides such as SnO₂, CuO, Fe₂O₃, and MoO₃, metal hydroxides such as Al(OH)₃, Mg(OH)₂, and ZnSn(OH)₆, metals containing boric acid, organic compounds containing boric acid, phosphoric-acid-esterified organic phosphorus compounds, and silicone polymers. The flame retardants used for the non-halogen flame-resisting resins according to the invention that are described later may be selected from the flame retardants described above.

The resin-sealed-type high-voltage diode using any of the flame resisting resins described above is manufactured in the following manner. Predetermined sheets, e.g., from 3 to 30 sheets, of mesa silicon diode chips, each designed to exhibit a predetermined reverse breakdown voltage, e.g., 1700 V, are laminated and bonded to each other with a solder such that the silicon diode chips are connected in series. After fixing metal axial leads to the upper and lower end faces of the chip laminate, the mesa bonding surfaces of the silicon diode chips are cleaned by etching and a surface treatment. A passivation treatment is applied to the cleaned mesa surfaces. Then, the diode chip laminate is sealed with a flame-resisting epoxy resin by transfer molding such that the diode chip laminate is in the center of the surrounding flame-resisting epoxy resin, to make the high-voltage diode. The high-voltage diode manufactured as described secures certain electrical insulation between the electrodes and certain mechanical strength. It can be used safely even when a high voltage between 5 kV and 50 kV is applied in the reverse direction of the diode.

Japanese Unexamined Laid Open Patent Applications 2000-44801 and H07(1995)-130919 and Japanese Patents 2825332 and 2860960 disclose other resin sealed semiconductor devices.

As described above, the problems of the conventional resin-sealed high-voltage diodes such as corrosion of the metal electrodes, parting and breaking of the metal films, and environmental pollution caused by the conventional flame retardants such as halogen-containing compounds and red phosphorus are obviated by employing a non-halogen flame retardant. However, the moisture resistance of the sealant resin is affected greatly by the high voltage (between 5 kV and 50 kV) applied to the high-voltage semiconductor devices. The high voltage between 5 kV and 50 kV is much higher than the voltage applied to other ordinary semiconductor devices. Therefore, the moisture resistance of the sealant resin is another problem specific to the high-voltage semiconductor devices that should be obviated. Moreover, a flame resisting resin is more expensive as the electrical conductivity thereof is lower.

The sealant resin affects semiconductor device reliability more greatly under wet conditions than under dry conditions due to moisture entering the sealant resin. It is considered that the moisture contained in the air enters the semiconductor device by infiltrating the resin itself and also through the boundaries between the resin and the metal terminals (the axial leads in the high-voltage diodes). The electrical characteristics of the semiconductor device are affected more adversely with an increasing amount of the moisture infiltrating in the vicinity of the semiconductor chip in the sealant resin, and to improve the moisture resistance of a semiconductor device, it is important to reduce the amount of moisture infiltrating the semiconductor device. In a high-voltage diode, ions and such electrolytic components are liable to be eluted from the resin into the infiltrated moisture, due to high temperature or a strong electric field. Since the electrical conductivity (hereinafter referred to as the “EC value”) of the moisture into which ions and such electrolytic components have been eluted increases, the electrical reliability of the semiconductor device is affected more adversely.

To improve the moisture resistance of the resin-sealed semiconductor device, it is important to find a resin or a resin composition that prevents moisture from infiltrating into the resin and prevents the resin components from being eluted into the moisture, and to employ this resin or the resin composition found for the semiconductor devices. Since the voltage applied to the circuit in the high-voltage diode is very high, it is very important to improve the moisture resistance of the resin for sealing the high-voltage diode. As described earlier, the flame resisting resin is more expensive as the electrical conductivity thereof is lower. Therefore, it is very important to decide on the electrical conductivity of the flame resisting resin suitable for the high-voltage diodes from the view point of cost reduction.

The moisture resistance of the semiconductor device is evaluated by the moisture resistance test. The moisture resistance test is called the “pressure cooker test” (hereinafter referred to as “PCT”). The PCT stores a resin-sealed high-voltage diode in an environment kept at the temperature of 121° C., under a pressure of 2 atmospheres, and in a relative humidity of 100% for 200 hours, and then evaluates the high temperature leakage current. The high temperature leakage current (hereinafter referred to as “IR2 value”) is a current at the rated reverse breakdown voltage measured in an insulation oil kept at 100° C.

As described above, PCT is a test for evaluating semiconductor devices. To evaluate many resins or resin compositions that exhibit excellent flame resistance, it is necessary to assemble evaluation samples for every resin or resin composition and to evaluate all the evaluation samples for all the resins and resin components. This requires a long lead time to obtain evaluation results and the resin costs soar.

In view of the foregoing, it would be desirable to provide a high-voltage diode using a sealant resin, which exhibits excellent flame resistance, selected solely by employing as the reference a characteristic value found to be appropriate in advance by the predetermined moisture resistance test without assembling high-voltage diode test samples using the sealant resins to be tested. It also would be desirable to provide a high-voltage diode that exhibits excellent moisture resistance, has a low manufacturing cost, and uses a cheap sealant resin that exhibits excellent moisture resistance.

The present invention is directed to achieving these objects and thereby overcoming or at least reducing the effects of one or more of the problems set forth above.

### SUMMARY OF THE INVENTION

According to an aspect of the invention, there is provided a diode exhibiting a high breakdown voltage. The diode includes one or more diode chips, and a flame-resisting non-halogen sealant resin sealing the one or more diode chips therein, wherein the electrical conductivity of the resin extract containing the components extracted from the flame-resisting non-halogen sealant resin under predetermined conditions is 250 μS/cm or lower.

Advantageously, the resin extract is obtained by dispersing the flame-resisting non-halogen sealant resin powder into pure water, the volume thereof is ten times as large as the volume of the sealant resin powder, and by heating the water with the sealant resin powder dispersed therein at 121° C. for 24 hours under a pressure of 2 atmospheres.

Advantageously, the flame-resisting non-halogen sealant resin is an epoxy resin.

### BRIEF DESCRIPTION OF THE DRAWINGS

The foregoing advantages and features of the invention will become apparent upon reference to the following detailed description and the accompanying drawings, of which:

FIG. 1 is a cross sectional view of a high-voltage diode according to an embodiment of the invention.

FIG. 2 is a graph describing the EC values of the resin extracts extracted under predetermined extraction conditions from multiple resin samples to be evaluated.

FIG. 3 is a graph relating the high temperature leakage currents (IR2 values) of the high-voltage diodes fabricated using the resin samples described in FIG. 2 with the resin samples.

FIG. 4 is a curve relating the IR2 values of the high-voltage diodes with the EC values of the resin samples.

FIG. 5 is a set of curves describing the aging of the reverse leakage currents with the passage of time.

### DETAILED DESCRIPTION OF SPECIFIC EMBODIMENTS

Now the invention will be described in detail hereinafter with reference to the drawing figures which illustrate the preferred embodiments of the invention. Although the invention is described in connection with the preferred embodiments thereof, changes and modifications are obvious to those skilled in art without departing from the true spirit of the invention. Therefore, the invention is to be understood not by the specific descriptions herein but by the appended claims.

FIG. 1 is a cross sectional view of a high-voltage diode according to an embodiment of the invention. The high-voltage diode according to this embodiment is manufactured in the following way. A pn-junction is formed by diffusing an impurity into an n-type silicon wafer, the specific resistance of which is suitable for obtaining a reverse breakdown voltage of 1700V, in an electric furnace at a certain high temperature. Predetermined sheets (e.g., 7 sheets) of the wafers with pn-junctions formed therein are laminated and bonded with solder 3. The wafer laminate is diced using a wire saw, blade saw, or similar cutter. The strains and contaminants caused by cutting in the cutting planes are removed by acid etching so that the original clean crystal planes are obtained. Then, the surfaces of the diced diode chip laminates are protected by coating passivation films 5 on the cleaned surfaces. A high-voltage diode is obtained by sealing the diode chip laminate with flame-resisting non-halogen resin 4 by transfer molding. Flame-resisting non-halogen resin 4 used for the high-voltage diode according to the invention exhibits improved moisture resistance.

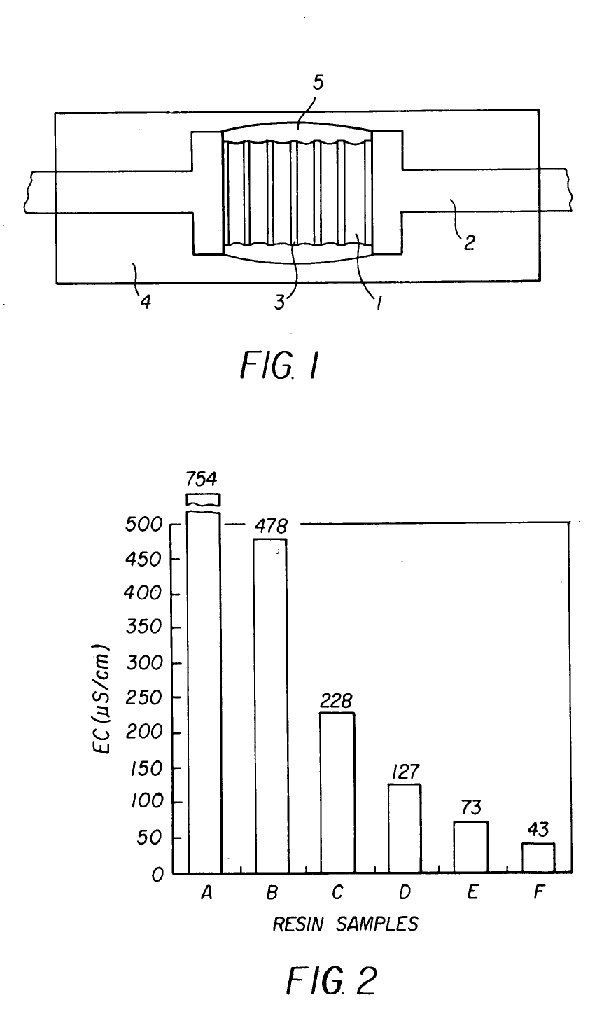

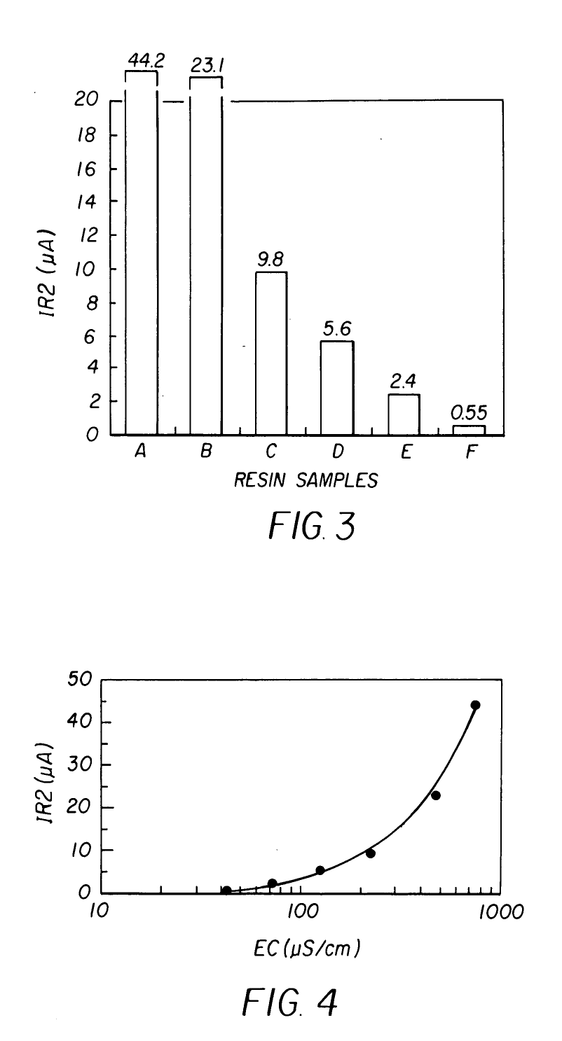

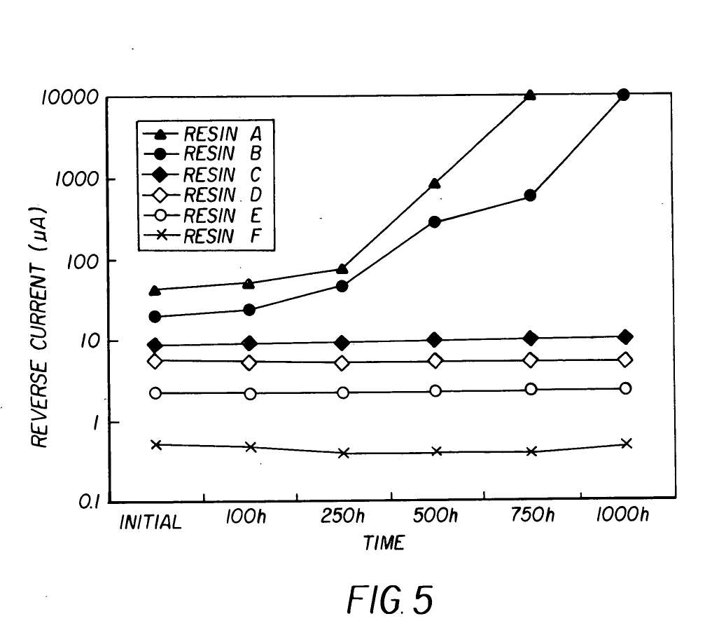

The method of selecting the flame resisting resin having improved moisture resistance will be described. The electrical conductivity values (EC values (μS/cm)) of the resin extracts obtained under predetermined extraction conditions from multiple resin samples to be evaluated are measured. The EC values are described for the resin samples in FIG. 2. High-voltage diodes are fabricated using the resin samples described in FIG. 2 for the sealant resins, and the high temperature leakage currents (IR2 values) thereof are measured after the moisture resistance tests. The IR2 values for the resin samples are described in FIG. 3. The relationships between the EC values and the IR2 values are obtained from FIGS. 2 and 3 and described in FIG. 4, and a reference electrical conductivity value (hereinafter referred to as a “reference EC value” (μS/cm)) is obtained for evaluating sealant resins.

The initial high-temperature reverse-leakage current (hereinafter referred to as the “initial IR2 value”), indicating that the high-voltage diode will exhibit excellent reliability, is determined to be 10 μA as shown in FIG. 5 from the relation between the initial IR2 values of the high-voltage diodes and the deterioration of the IR2 values due to aging. The IR2 values of the high-voltage diodes including the initial values thereof are measured in the temperature humidity bias test, which is one of the long-term reliability tests for testing high-voltage diodes. A reference EC value is determined to be 250 μS/cm, which is the EC value found from FIG. 4 to correspond to the IR2 value of 10 μA.

Resins usable for sealing the high-voltage diode according to the invention are selected by measuring the EC values of the resin samples and by comparing the measured EC values with the above described reference EC value. The selected resins are used for sealing the high-voltage diodes according to the invention. More reliable sealant resin have an extract that exhibits an EC value of 200 μS/cm or lower, and these are used to seal the high-voltage diode according to the invention.

Now the high-voltage diode according to the invention will be described in detail. Six kinds of flame-resisting cresol-novolak epoxy resins A, B, C, D, E, and F are prepared for sealing high-voltage diodes. The amount of additive for improving flame resistance is increased from the resin A to the resin F. Therefore the flame resistance increases from the resin A to the resin F. The extract EC values of the resins A through F are measured. The results are described in FIG. 2. The horizontal axis of FIG. 2 represents the kinds of the resins (A, B, C, D, E, and F), and the vertical axis represents the EC values (μS/cm). The costs increase from resin A to resin F.

Now the method of measuring the EC values will be described in detail. Extracts of the resins A through F are prepared and the electrical conductivity values thereof are measured. The resin extracts are prepared in the following manner. Uncured tablets of the resins A through F are pulverized and the powder resins are cured at 175° C. for 1 hour. After curing, the powder resins are further pulverized in an automatic mortar. The further pulverized powder resins are filtered through a filter of 100 mesh (with a cross of 150 μm). Five grams of the filtered powder are dispersed into 50 ml of pure water and heated at 121° C. for 24 hours, and the electrical conductivity values of the resulting resin extracts are measured. The electrical conductivity values of the resins A and B are much higher than those of the resins C through F, presumably because more ion components are extracted from the resins A and B than from the resins C through F.

High-voltage sample diodes are fabricated using resins A through F. The PCT, which is an accelerated humidity resistance test, is conducted for 200 hours on the fabricated high-voltage sample diodes at the temperature of 121° C., under a pressure of 2 atmospheres, and at a relative humidity of 100% RH. Then, the high-voltage sample diodes are put in an insulation oil, a rated reverse breakdown voltage of 8 kV is applied to the high-voltage sample diodes, and the high-temperature reverse leakage currents (IR2 values) of the high-voltage sample diodes are measured at 100° C. The results are shown in FIG. 3. The relationships between the resulting EC values and the high-temperature reverse leakage current IR2 values are obtained from FIGS. 2 and 3 and shown in FIG. 4.

Since the generated heat amount increases as the IR2 value becomes higher, thermal breakdown of the high-voltage diode may occur more often as the IR2 value becomes higher, impairing the functions of the high-voltage diode. In other words, there exists a certain relation between the IR2 value and the reliability of the high-voltage diode. Therefore, the relationships between the IR2 values and the reliability of the high-voltage diodes are investigated by a temperature humidity bias test (hereinafter referred to as a “THB test”), which is one of the tests for evaluating the reliability of the high-voltage diodes.

The THB test is conducted at 85° C., at a relative humidity of 100% RH, and under an applied voltage of 80% of the rated reverse breakdown voltage (8 kV) for 1000 hours. Results are shown in FIG. 5. As described in FIG. 5, the IR2 values of the high-voltage diodes using resins A and B, which are higher than 10 μA at the rated reverse breakdown voltage of 8 kV initially, increase gradually with the passage of time and increase sharply as the time exceeds 250 hours to the longer side. Thus, by measuring the EC values of the resin extracts under the predetermined conditions, only flame resisting resins C, D, E, and F, the EC values of which are 250 μS/cm or lower, are selected for sealing high-voltage diodes with excellent moisture resistance. More preferably, flame resisting resins D, E, and F, the EC values of which are 200 μS/cm or lower, are employed for sealing high-voltage diodes with excellent moisture resistance. Since the EC value of the sealant resin extract is preferably 250 μS/cm or lower and, more preferably, 200μS/cm or lower according to the invention, a cheaper resin may be selected within the above described EC range.

As described above, sealant resins for high-voltage diodes with excellent moisture resistance are selected according to the invention by employing the EC value, which has been discovered to be appropriate as a reference value. The invention does not require the assembling of a high-voltage diode for testing, but achieves its results by conducting the predetermined humidity resistance test on the sealant resin samples. The sealant resin selection according to the invention facilitates reducing the resin costs. Therefore, the high-voltage diode with excellent humidity resistance is manufactured with low manufacturing costs using any of the selected resins.

Thus, a diode exhibiting a high breakdown voltage has been described according to the present invention. Many modifications and variations may be made to the techniques and structures described and illustrated herein without departing from the spirit and scope of the invention. Accordingly, it should be understood that the methods and devices described herein are illustrative only and are not limiting upon the scope of the invention.

1. A diode exhibiting a high breakdown voltage, the diode comprising:
one or more diode chips; and
a flame-resisting non-halogen sealant resin sealing the one or more diode chips therein;
wherein the electrical conductivity of the resin extract containing the components extracted from the flame-resisting non-halogen sealant resin under predetermined conditions is 250 μS/cm or lower.

2. The diode according to claim 1, wherein the predetermined conditions comprise dispersing the flame-resisting non-halogen sealant resin powder into pure water, the volume of which is ten times as large as the volume of the sealant resin powder, and by heating the water with the sealant resin powder dispersed therein at 121° C. for 24 hours under the pressure of 2 atmospheres.

3. The diode according to claim 1, wherein the flame-resisting non-halogen sealant resin comprises an epoxy resin.

4. The diode according to claim 2, wherein the flame-resisting non-halogen sealant resin comprises an epoxy resin.

5. The diode according to claim 1, wherein the electrical conductivity of the resin extract containing the components extracted from the flame-resisting non-halogen sealant resin under predetermined conditions is 200 μS/cm or lower.

6. A method of selecting a flame-resisting non-halogen sealant resin for use in a semiconductor device, comprising
dispersing the flame-resisting non-halogen sealant resin powder into pure water, the volume of which is ten times as large as the volume of the sealant resin powder;
heating the water with the sealant resin powder dispersed therein at 121° for 24 hours under the pressure of 2 atmospheres, whereby components are extracted from the resin into the water to form a resin extract, and
selecting resins for which the electrical conductivity of the resin extract containing the components extracted from the flame-resisting non-halogen sealant resin is 250 μS/cm or lower.

7. The method according to claim 6, wherein resins are selected for which the electrical conductivity of the resin extract containing the components extracted from the flame-resisting non-halogen sealant resin is 200 μS/cm or lower.

8. A method of selecting a flame-resisting non-halogen sealant resin for use in a semiconductor device, comprising:
exposing resins to water at predetermined levels of heat and pressure, whereby components are extracted from the resin into the water to form a resin extract, and
selecting those resins for which the electrical conductivity of a resin extract containing the components extracted from the flame-resisting non-halogen sealant resin is 250 μS/cm or lower.

9. A method of selecting a flame-resisting non-halogen sealant resin for use in a semiconductor device as claimed in claim 8, in which resins are selected for which the electrical conductivity of a resin extract containing the components extracted from the flame-resisting non-halogen sealant resin is 200 μS/cm or lower.
